(19) United States
(12) Patent Application Publication
(10) Pub. No.: US 2008/0014708 A1
(43) Pub. Date: Jan. 17, 2008

(54) Method of fabricating semiconductor device

(75) Inventor: Young-mok Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., LTD

(21) Appl. No.: 11/819,072

(22) Filed: Jun. 25, 2007

(30) Foreign Application Priority Data
Jul. 14, 2006 (KR) 10-2006-0066197

(51) Int. Cl. H01L 21/762

(52) U.S. Cl. 438/401; 257/E21.546

(57) ABSTRACT

Disclosed is a method of fabricating a semiconductor device having improved processing stability. A protection layer may be formed on a semiconductor substrate. A sacrificial layer having an etch selectivity with respect to the protection layer may be formed on the protection layer. A part of the sacrificial layer may be selectively etched, thereby forming an alignment key. An aligned well may be formed using the alignment key. An aligned isolation layer may be formed in the semiconductor substrate having the well formed therein, using the alignment key.

### PRIORITY STATEMENT

This application claims priority under 35 U.S.C. §119 to Korean Patent Application No. 10-2006-0066197, filed on Jul. 14, 2006, in the Korean Intellectual Property Office (KIPO), the entire contents of which are incorporated herein by reference.

### BACKGROUND

1. Field

Example embodiments relate to a method of fabricating a semiconductor device. Other example embodiments relate to a method of fabricating a high-voltage semiconductor device.

2. Description of the Related Art

Driving integrated circuits of a high-voltage semiconductor device, for example, a liquid crystal display (LCD) and/or a plasma display panel (PDP) device, may require a deep well in a semiconductor substrate. In the high-voltage semiconductor device, a deep well may be formed before an active region is defined in the semiconductor substrate, and the deep well may be formed, for example, by implanting impurity ions into the semiconductor substrate and performing a well drive-in process at an increased temperature and for an increased period of time.

However, the process of forming the deep well does not cause a step height difference on the semiconductor substrate, and thus, may cause an alignment problem later during a photo lithography process for defining an active region after forming the deep well. In order to solve the problem, the conventional art discloses methods of forming a step part for forming an alignment key on a semiconductor substrate.

FIG. 1 is a sectional view illustrating a conventional method of fabricating a semiconductor device. Referring to FIG. 1, an N-well 14, a P-well 24, and a PP-well 34 may be formed on a semiconductor substrate 10 having a scribe line defined therein. A pad oxide layer 42, a silicon nitride layer 44, and an anti-reflective layer 46 may be sequentially formed on the semiconductor substrate 10. A photoresist pattern 50 may be provided to define an active region of the semiconductor substrate 10, and may be formed on the anti-reflective layer 46 using an alignment key formed in the scribe line. The alignment key may be defined by a step height difference which is recessed from the surface of the semiconductor substrate 10 in the scribe line. However, the step height difference may cause processing failures in subsequent processes. For example, the silicon nitride layer 44 may remain in the step part during the formation of an isolation layer (not shown), which deteriorates the reliability of a semiconductor device.

### SUMMARY

Example embodiments provide a method of fabricating a semiconductor device having improved processing stability. According to example embodiments, there is provided a method of fabricating a semiconductor device. A protection layer may be formed on a semiconductor substrate. A sacrificial layer having an etch selectivity with respect to the protection layer may be formed on the protection layer. A part of the sacrificial layer may be selectively etched, thereby forming an alignment key. An aligned well may be formed using the alignment key. An aligned isolation layer may be formed in the semiconductor substrate having the aligned well formed therein, using the alignment key.

In accordance with example embodiments, the method may further include forming another well, which may not be aligned in the semiconductor substrate, before forming the protection layer. The aligned well may be surrounded by the non-aligned well, and may have a conductivity type opposite to that of the non-aligned well.

Further, forming the aligned well may include forming an aligned photoresist pattern using the alignment key, and implanting impurity ions into the semiconductor substrate using the photoresist pattern as a mask. Forming the aligned isolation layer may include forming a plurality of aligned trenches using the alignment key, and forming a planarized insulating layer to fill the trenches. Forming the alignment key may include forming a photoresist pattern exposing a part of the sacrificial layer on the protection layer, and etching a part of the sacrificial layer using the photoresist pattern as a mask so as to form a step height difference between the protection layer and the sacrificial layer.

In accordance with example embodiments, the method may further include implanting impurity ions into the semiconductor substrate using the photoresist pattern exposing a part of the sacrificial layer as a mask, thereby forming an additional well. In accordance with example embodiments, before forming the protection layer, the method may further include providing a semiconductor substrate without an isolation layer, and implanting impurity ions into the semiconductor substrate, thereby forming the non-aligned well.

The semiconductor substrate may include a device region and a scribe line region, and the alignment key may be formed in the scribe line region. The sacrificial layer may include a silicon oxide layer, and the protection layer may include a silicon nitride layer. The protection layer may further include a silicon oxide layer between the silicon nitride layer and the semiconductor substrate. The sacrificial layer may be formed at a thickness of about 100 to about 5,000 Å.

In accordance with example embodiments, the method may further include forming a first photoresist pattern on the protection layer, before etching a part of the sacrificial layer. In accordance with example embodiments, the method may further include implanting impurity ions into the semiconductor substrate using the first photoresist pattern as a mask, thereby forming the additional well, before forming the aligned well. In accordance with example embodiments, forming the aligned well may include forming an aligned second photoresist pattern using the alignment key, and implanting impurity ions into the semiconductor substrate using the second photoresist pattern as a mask. The non-aligned well may be an n-type well, the additional well may be a p-type well, and the aligned well may be a p-type pocket well surrounded by the first well. The isolation layer may include a planarized insulating layer formed using the protection layer as an etch stop layer.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a sectional view illustrating a conventional method of fabricating a semiconductor device; and

FIGS. 2-8 are sectional views illustrating a method of fabricating a semiconductor device according to example embodiments.

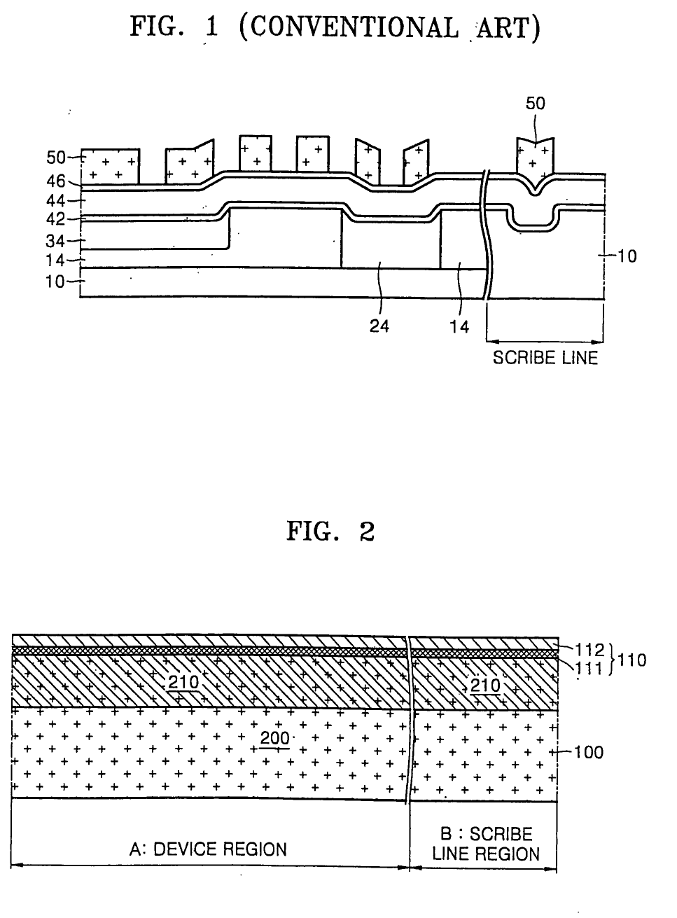

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully hereinafter with reference to the accompanying drawings, in which example embodiments are shown. Example embodiments may, however, be embodied in many different forms and should not be construed as being limited to the embodiments set forth herein. Rather, these embodiments are provided so that this disclosure will be thorough and complete, and will fully convey the scope of example embodiments to those skilled in the art. In the drawings, the thicknesses of layers and regions are exaggerated for clarity. Like numbers refer to like elements throughout the specification.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In example embodiments, a semiconductor device may be employed in products requiring an increased operating voltage. For example, the semiconductor device may be used to drive integrated circuits of a display device, for example, a liquid crystal display (LCD) and/or a plasma display panel (PDP). However, the semiconductor device according to example embodiments may not be limited to products requiring an increased operating voltage.

FIGS. 2-8 are sectional views illustrating a method of fabricating a semiconductor device according to example embodiments. Referring to FIG. 2, a protection layer 110 may be formed on a semiconductor substrate 100. For example, the protection layer 110 may include a silicon oxide layer 111 and/or a silicon nitride layer 112. Optionally, a first well 210 may be formed before or during the formation of the protection layer 110.

The semiconductor substrate 100 may include a device region A where unit devices will be formed, and a scribe line region B. An example of a unit device may be a transistor and/or a capacitor. The scribe line region B may be used to divide the semiconductor device formed on the semiconductor substrate 100 into chip units. For example, the semiconductor substrate may include a p-type silicon wafer.

More specifically, a silicon oxide layer 111 may be formed on the semiconductor substrate 100. For example, the surface of the semiconductor substrate 100 including the silicon wafer may be thermally oxidized at a temperature of about 800° C. to about 900° C., thereby forming the silicon oxide layer 111 at a thickness of about 200 Å. The silicon oxide layer 111 may function to relieve the stress applied from a silicon nitride layer 112 to be formed later on the semiconductor substrate 100. However, in other example embodiments, the silicon oxide layer 111 may be omitted or may be replaced with a different insulating material.

Optionally, impurity ions may be implanted into the whole surface of the semiconductor substrate 100 where the silicon oxide layer 111 is formed, thereby forming a first well 210 in the semiconductor substrate 100. For example, when n-type impurities, e.g., phosphorous, are used, the first well 210 may be formed as an n-type well. A body 200 of the semiconductor substrate 100, which is diode-connected with the first well 210, may be of a p-type. Alternatively, the body 200 may be of an n-type, and the first well 210 may be of a p-type.

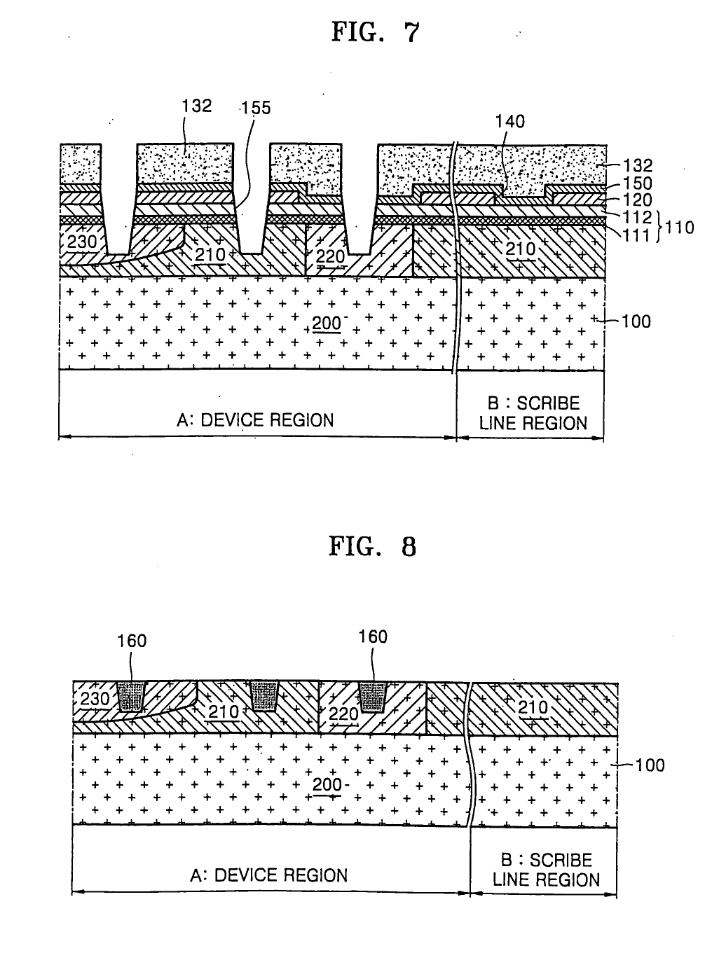

A silicon nitride layer 112 may be formed on the silicon oxide layer 111. For example, the silicon nitride layer 112 may be formed using a low pressure chemical vapor deposition (LPCVD) method to a thickness of about 1,000 Å. The silicon nitride layer 112 may be used as a mask during etching of a trench 155 (FIG. 7), and may be used as an etch-stop layer during a chemical mechanical polishing (CMP) process. In example embodiments, a silicon oxynitride layer may be used instead of the silicon nitride layer 112. In other example embodiments, an oxide layer and a nitride layer, which are composed of different materials, may be used according to the semiconductor substrate 100 instead of the silicon oxide layer 111 and the silicon nitride layer 112.

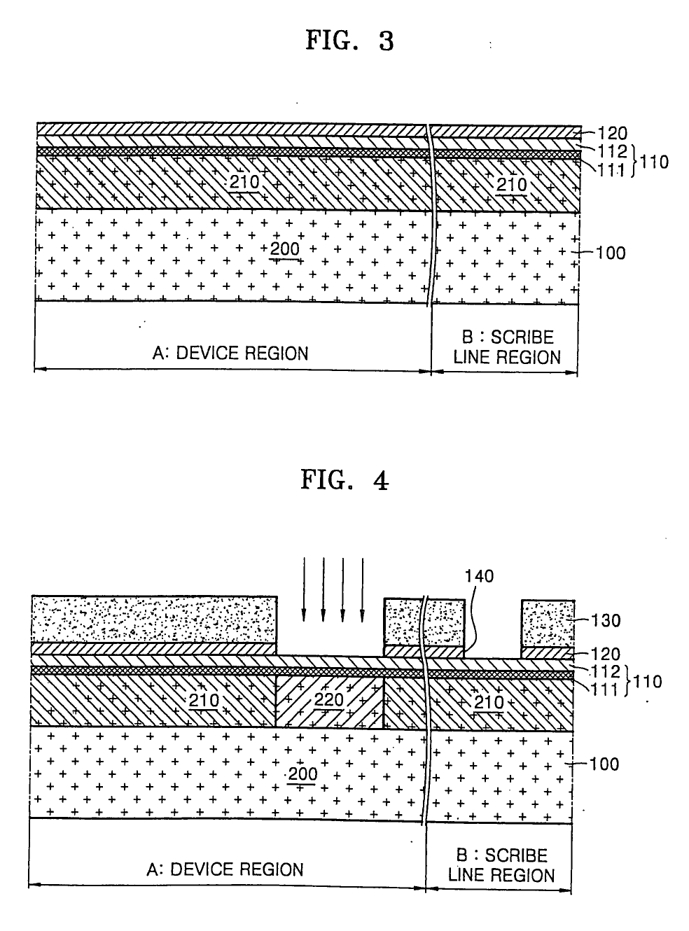

Referring to FIG. 3, a sacrificial layer 120 may be formed on the protection layer 110. The sacrificial layer 120 may be used as an alignment key until an isolation layer 160 (FIG. 8) is formed. The sacrificial layer 120 may be composed of a material having an etch selectivity with respect to an upper layer of the protection layer 110. For example, the sacrificial layer 120 may include a silicon oxide layer which may have an etch selectivity to the silicon nitride layer 112 as an upper layer of the protection layer 110. In example embodiments, the etch selectivity between two material layers means that a ratio of the etch rates of two material layers may be at least about 10:1 or higher. For example, the sacrificial layer 120 may be formed with a thickness of about 100 Å to about 5,000 Å such that a step height difference for alignment exists when an alignment key 140 (FIG. 4) may be formed.

Referring to FIG. 4, a part of the sacrificial layer 120 may be removed, thereby forming the alignment key 140. For example, the alignment key 140 may refer to a step part of the sacrificial layer 120 formed on the protection layer 110. For example, a step height difference and an illumination difference between the sacrificial layer 120 and the protection layer 110 in the alignment key 140 may be used for alignment during a photolithography process. A first photoresist pattern 130 may be formed on the sacrificial layer 120. The first photoresist pattern 130 may be formed such that a predetermined or given portion of the sacrificial layer 120 for forming a second well 220 and the alignment key 140 may be exposed.

A part of the sacrificial layer 120 may be etched and removed using the first photoresist pattern 130 as a mask, thereby forming the alignment key 140. For example, the portion of the sacrificial layer 120 exposed by the first photoresist pattern 130 may be etched. For example, the sacrificial layer 120 may be etched such that the protection layer 110 disposed below the sacrificial layer 120 may be exposed, to provide a step height difference of the alignment key 140.

Impurity ions may be implanted into a predetermined or given region of the semiconductor substrate 100 using the first photoresist pattern 130 as a mask. The implanted impurity ions may be diffused by a thermal treatment, thereby forming the second well 220 in the semiconductor substrate 100. When p-type impurity ions, e.g., boron, are implanted, the second well 220 may be defined as a p-type well.

Although FIG. 4 illustrates that the second well 220 is formed only in the device region A, the second well 220 may be formed in the scribe line region B exposed by the first photoresist pattern 130. In example embodiments, the first photoresist pattern 130 may be commonly used to form the alignment key 140 and the second well 220. The high-cost photolithography process may be shortened. However, the alignment key 140 and the second well 220 may be formed using respective photolithography patterns in other example embodiments.

Because the alignment key 140 does not accompany a step height difference of the semiconductor substrate 100, processing failures, which may be raised due to the step height difference of the semiconductor substrate 100, may not occur, unlike the conventional method.

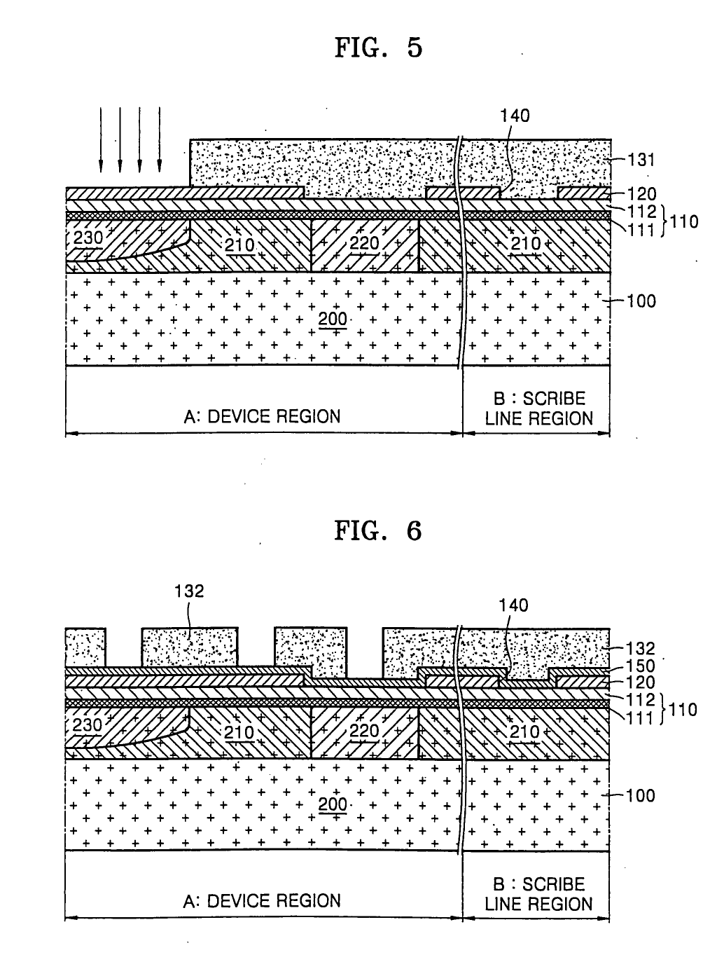

Referring to FIG. 5, a second photoresist pattern 131, which is aligned using the alignment key 140, may be formed. In example embodiments, aligning by the alignment key 140 may mean that the semiconductor substrate 100 and a mask (not shown) may be aligned based on the alignment key 140. Thus, patterns on the mask may be repetitively aligned on the semiconductor substrate 100.

Impurity ions may be implanted into a predetermined or given region of the semiconductor substrate 100 using the second photoresist pattern 131 as a mask. The second photoresist pattern 131 may be formed such that a predetermined or given portion of the sacrificial layer 120 or the protection layer 110 may be exposed in order to form a third well 230. The implanted impurity ions may be diffused into the semiconductor substrate 100 by a thermal treatment, thereby forming the third well 230. For example, the third well 230 may be formed to be surrounded by the first well 210, and thus, the third well 230 may be referred to as a pocket well. However, the third well 230 may not be limited to a pocket-shaped well as above.

For example, when p-type impurities are used, the third well 230 may be formed as a pocket p-type well. The third well 230 may have a shallower junction depth than that of the first well 210, and may be surrounded by the first well 210 so as not to directly contact the body 200.

Referring to FIG. 6, a third photoresist pattern 132, which is aligned using the alignment key 140, may be formed. The third photoresist pattern 132 may be formed to expose a predetermined or given portion of the semiconductor substrate 100 in order to form the isolation layer 160 of FIG. 8.

An anti-reflective layer (ARL) 150 may be selectively formed on the sacrificial layer 120 before forming the third photoresist pattern 132. Because the anti-reflective layer 150 is formed along the step height difference of the sacrificial layer 120 and the protection layer 110, the step height difference of the alignment key 140 may be sufficiently maintained.

Referring to FIGS. 7 and 8, a process of forming an isolation layer of shallow trench isolation (STI) type will be explained. However, isolation layers having different shapes may be formed in other example embodiments.

Referring to FIG. 7, a part of the semiconductor substrate 100 may be removed using the third photoresist pattern 132 as a mask, thereby forming a plurality of trenches 155. For example, the anti-reflective layer 150, the protection layer 110, and the semiconductor substrate 100, which are exposed by the third photoresist pattern 132, may be etched at a predetermined or given depth.

Referring to FIG. 8, the trenches 155 may be filled with an insulating material, thereby forming the isolation layer 160. After the isolation layer 160 is formed, the sacrificial layer 120 and the alignment key 140 may be removed.

For example, the isolation layer 160 may be formed by filling the trenches 155 with an insulating material and planarizing the insulating material until the protection layer 110 is exposed. For example, the protection layer 110 may be used as an etch stop layer of the planarizing process for forming the isolation layer 160. For example, the planarizing may use a chemical mechanical polishing (CMP) method and/or an etch-back method. The sacrificial layer 120 and the alignment key 140 may be removed during the planarizing process or during a subsequent cleaning process. Processes for forming circuit devices, e.g., a transistor, and processes for forming interconnections may be performed using methods which are well known to those skilled in this field.

While example embodiments have been particularly shown and described with reference to example embodiments thereof, it will be understood by those of ordinary skill in the art that various changes in form and details may be made therein without departing from the spirit and scope of the following claims.

What is claimed is:

1. A method of fabricating a semiconductor device comprising:
forming a protection layer on a semiconductor substrate;
forming a sacrificial layer having an etch selectivity with respect to the protection layer on the protection layer;
selectively etching a part of the sacrificial layer, thereby forming an alignment key;
forming an aligned well, using the alignment key; and
forming an aligned isolation layer in the semiconductor substrate having the well formed therein, using the alignment key.

2. The method of claim 1, further comprising:
forming another well, which is not aligned in the semiconductor substrate, wherein the aligned well is surrounded by the non-aligned well, and has a conductivity type opposite to that of the non-aligned well, before forming the protection layer.

3. The method of claim 1, wherein forming the aligned well comprises:
forming an aligned photoresist pattern using the alignment key; and
implanting impurity ions into the semiconductor substrate using the photoresist pattern as a mask.

4. The method of claim 1, wherein forming the aligned isolation layer comprises:
forming a plurality of aligned trenches using the alignment key; and
forming a planarized insulating layer to fill the trenches.

5. The method of claim 4, wherein forming the aligned isolation layer further comprises:
forming an anti-reflective layer on the sacrificial layer, before forming the plurality of aligned trenches.

6. The method of claim 1, wherein forming the alignment key comprises:
forming a photoresist pattern exposing a part of the sacrificial layer on the protection layer; and
etching a part of the sacrificial layer using the photoresist pattern as a mask so as to form a step height difference between the protection layer and the sacrificial layer.

7. The method of claim 6, further comprising:
implanting impurity ions into the semiconductor substrate using the photoresist pattern exposing a part of the sacrificial layer as a mask, thereby forming an additional well.

8. The method of claim 1, wherein the semiconductor substrate includes a device region and a scribe line region, and the alignment key is formed in the scribe line region.

9. The method of claim 1, wherein the sacrificial layer includes a silicon oxide layer, and the protection layer includes a silicon nitride layer.

10. The method of claim 9, wherein the protection layer further includes a silicon oxide layer between the silicon nitride layer and the semiconductor substrate.

11. The method of claim 9, wherein the sacrificial layer is formed at a thickness of about 100 Å to about 5,000 Å.

12. The method of claim 2, before forming the protection layer, further comprising:
providing a semiconductor substrate without an isolation layer; and
implanting impurity ions into the semiconductor substrate, thereby forming the non-aligned well.

13. The method of claim 7, further comprising:
forming a first photoresist pattern on the protection layer, before selectively etching a part of the sacrificial layer.

14. The method of claim 13, further comprising:
implanting impurity ions into the semiconductor substrate using the first photoresist pattern as a mask, thereby forming the additional well, before forming the aligned well.

15. The method of claim 14, wherein forming the aligned well comprises:
forming an aligned second photoresist pattern using the alignment key; and
implanting impurity ions into the semiconductor substrate using the second photoresist pattern as a mask.

16. The method of claim 15, wherein the non-aligned well is an n-type well, the additional well is a p-type well, and the aligned well is a p-type pocket well surrounded by the non-aligned well.

17. The method of claim 1, wherein the isolation layer includes a planarized insulating layer formed using the protection layer as an etch stop layer.
